(19) United States
(12) Patent Application Publication
(10) Pub. No.: US 2007/0040565 A1
(43) Pub. Date: Feb. 22, 2007

(54) Compliant probes and test methodology for fine pitch wafer level devices and interconnects

(75) Inventors: Jayasanker Jayabalan, Singapore (SG); Mihai Dragos Rotaru, Singapore (SG); Mahadevan Krishna Iyer, Singapore (SG); Andrew Tay Ah Ong, Singapore (SG)

Correspondence Address: STEPHEN B. ACKERMAN, 28 DAVIS AVENUE, POUGHKEEPSIE, NY, 12603, US

(73) Assignees: National University of Singapore, Agency For Science, Technology and Research; Georgia Tech Research Coporation

(21) Appl. No.: 11/207,336

(22) Filed: Aug. 19, 2005

(51) Int. Cl. G01R 31/26

(52) U.S. Cl. 324/765

(57) ABSTRACT

A compliant interposer sheet probe card and a method for testing a wafer or a wafer level package using the probe card are described. Test electronic circuits are connected on one side of a multi-layer substrate. A top side of a compliant interposer sheet is connected to an opposite side of the multi-layer substrate. A wafer or a wafer level package to be tested is contacted with pins on a bottom side of the compliant interposer sheet whereby the wafer or wafer level package can be tested.

### RELATED PATENT APPLICATIONS

This patent application is related to U.S. patent application Ser. No. 10/667,008, filed on Sep. 17, 2003 and U.S. patent application Ser. No. 10/392,084, filed on Mar. 20, 2003, both incorporated by reference herein in their entirety.

### BACKGROUND OF THE INVENTION

(1) Field of the Invention

The invention generally relates to semiconductor integrated circuit devices and, more particularly, to testing probes and methodology for integrated circuit (IC) devices.

(2) Description of Prior Art

In conventional IC packaging, test and bum-in are done after the IC is packaged as a Quad Flat Package (QFP), ball grid array (BGA), or chip scale package (CSP). But this singulated device test and bum-in at the packaged IC level is very expensive.

Wafer level packages (WLP) offer batch processing capability at the wafer level. WLP is a new paradigm in microelectronic packaging which demands new test solutions. Related U.S. patent application Ser. Nos. 10/667,008 and 10/392,084 describe the processes involved in fabrication of WLP interconnects. Since test and burn-in can be performed in one go with many devices in parallel, test productivity is multiplied while test cost is significantly reduced. But the need to make electrical contacts to the interconnecting structures with fine pitches of the order of 100 microns presents tremendous challenges to the conventional wafer level test system. Furthermore, the bandwidth requirements present difficulties in the selection of materials as well as integration and fabrication methods.

Presently, testing of wafer level package devices is performed using individual probes directly on the wafer. It is found that this approach is not applicable to the fine pitch-wafer level packaged device with a large number of inputs/outputs. Due to the unique mechanical and electrical requirements, a special compliant sheet interposer supported on a multi-layer low loss substrate board has been found to be effective. The interposer sheet itself acts as a two dimensional flat probe.

There are many test probes available currently that meet some but not all of the test needs of VLSI semiconductor devices. The coaxial probes and coplanar probes, for instance, provide high frequency operation but they are too bulky and so they are suited for low pin count device testing only.

The cantilever beam probes have been used traditionally in the industry for testing chips with pin counts on the order of hundreds but they are very bad for high frequency testing due to the huge inductance of long lead length. There are Cobra probes, membrane and DoD (die-on-die) probes from various sources but their problem is that they do not provide reliable contacts and are not scalable to very high pin counts (beyond a thousand or two).

It is desired to provide very high pin count (on the order of 1000's of pins per square centimeter), vertically compliant, high frequency and high temperature test probes to meet the demands of wafer scale probing of semiconductors as against the testing of individual chips.

EP Patent 1077381 A2 describes a flexible substrate probe card using a continuum of elastic material for compliance with level transitions in a first wiring. U.S. Pat. No. 6,710,609 B2 discloses a mosaic decal probe card that uses a mosaic of probe chips that have spring contacts to match to the wafer under test. The spring takes the compliance and also slides during thermal excursions. The coefficient of thermal expansion (CTE) of the membrane ring on which the probe chips are assembled is matched to that of the wafer under test (WUT) substrate. The paper, “Test Bench modeling and characterization for fine pitch wafer level packaged devices”, by the inventors Jayasanker et al, IEEE Electronic Packaging Technology Conference, Singapore, 2004, discusses the model and measurement aspects of a specific piece of hardware without revealing details of the hardware and implementation.

### SUMMARY OF THE INVENTION

A principal object of the present invention is to provide very high pin count vertically compliant, high frequency and high temperature test probes for wafer scale probing.

A second object of the present invention is to provide a probing and test methodology for fine pitch wafer level devices operating at multi-gigahertz frequencies.

Another object of the invention is to provide test hardware to be used in the testing methodology of the present invention.

Yet another object is to provide for an automatic test equipment interface for the test hardware of the present invention.

In accordance with the objects of the invention, a method for testing a wafer or a wafer level package is achieved. Test electronic circuits are connected on one side of a multi-layer substrate. A top side of a compliant interposer sheet is connected to an opposite side of the multi-layer substrate. A wafer or a wafer level package to be tested is contacted with pins on a bottom side of the compliant interposer sheet whereby the wafer or wafer level package can be tested.

Also in accordance with the objects of the invention, a method for fabricating a compliant interposer sheet probe card for wafer level testing or wafer level package testing is achieved. A multi-layer substrate is formed. A compliant interposer sheet is formed. Metallization is deposited on the compliant interposer sheet to form contact probes. The contact probes are connected at one end to the multi-layer substrate. The opposite end of the contact probes is aligned to a wafer or to a wafer level package to be tested.

Also in accordance with the objects of the invention, a compliant interposer sheet probe card for wafer level testing or wafer level package testing is achieved. The probe card comprises a multi-layer substrate, a compliant interposer sheet, and contact probes on the compliant interposer sheet wherein one end of the contact probes is connected to the multi-layer substrate and an opposite end of the contact probes is aligned to a wafer or to a wafer level package to be tested.

### BRIEF DESCRIPTION OF THE DRAWINGS

In the accompanying drawings forming a material part of this description, there is shown:

FIG. 1 schematically illustrates in cross-sectional representation a first preferred embodiment test system of the present invention.

FIGS. 2A and 2B schematically illustrate in cross-sectional representation a second preferred embodiment test system of the present invention.

FIG. 3 illustrates in top view representation a prototype device under test (DUT) of the present invention.

FIG. 4 graphically illustrates insertion loss of the DUT of FIG. 3.

FIGS. 5A and 5B illustrate in top view the prototype test hardware of the present invention.

FIG. 6 illustrates in top view and signal layer view the prototype interposer sheet and printed circuit board (PCB) of the present invention.

FIG. 7 illustrates in cross-sectional representation a prototype multi-layer structure of the present invention.

FIG. 8 illustrates in top view a probe sheet of the present invention.

FIG. 9A illustrates in top view and FIG. 9B illustrates in side view a probe and DUT of the present invention.

FIG. 10 illustrates in cross-sectional representation a probe without protrusions of the present invention.

FIG. 11 illustrates in cross-sectional representation a probe with protrusions of the present invention.

FIGS. 12 through 15 illustrate in top view alternative interposer mesh formations of the present invention.

FIG. 16 illustrates in top view an automatic test equipment interface formation of the prior art.

FIG. 17 illustrates in top view an automatic test equipment interface formation of the present invention.

FIGS. 18A through 18J graphically illustrate simulated results (insertion losses) for the PCB-compliant sheet structure of the present invention.

FIGS. 19 through 22 graphically illustrate system level simulation and measurement of the prototype structure of the present invention.

FIG. 23A illustrates a top view and FIG. 23B illustrates a side view of a probe and DUT of the present invention for low pin count applications.

FIG. 24A illustrates a top view and FIG. 24B illustrates a side view of a probe and DUT of the present invention for high pin count applications.

FIGS. 25A through 25C schematically illustrate in top view preferred space transformer structures of the present invention.

### DESCRIPTION OF THE PREFERRED EMBODIMENTS

The detailed implementation of our probing and test methodology for the fine pitch wafer level devices operating at multi-gigahertz frequencies is described in this invention.

Multiple types of wafer level package interconnects are addressed in the present invention and are testable by the method of the invention. The purpose is to be able to verify that the interconnects are well formed without manufacturing defects so that high speed electronic signals can pass through them efficiently. The test signals are launched from external equipment and sent via the connectors, printed circuit board, compliant sheet, WLP interconnect and back to the test equipment through the WLP interconnect, compliant sheet, printed circuit board and connectors. The difference between the signal sent and signal received gives an indication of the quality of the interconnect. The part played by the compliant sheet is that it provides good electrical contact and also cushions the differences in the height of the interconnects without damaging them.

FIG. 1 illustrates a wafer or WLP 10 to be tested, a probe card 12, a Sub Miniature version A (SMA) connector 14, and input/output signal coaxial cables 16. There may be many I/O signals. The compliant interposer sheet of the invention 18 is shown. Metallization contacts or probes 111 are shown on the compliant interposer sheet 18. If the device under test (DUT) 10 is a plain wafer, connections are made between the probes 111 and pads 113, such as aluminum or gold, etc. If the DUT is a wafer level package, connections are made between the probes 111 and interconnects 113. The interconnects 113 may be solder balls, solder columns, or bed of nails interconnects, for example.

The present invention and test methodology is applicable to the types of interconnects mentioned above and also to many other types of interconnects or combinations of them found in the literature. For the purpose of demonstration of the proof of the inventors' probing and test methodology, the inventors have developed a prototype test system with the ability to probe 100 micron pitch wafer level package interconnects. The probe design is relatively simple for low pin counts, but for high pin count ultra fine pitches, device probing will start to have challenging contact problems due to compliance issues with large pin area arrays. Also insertion losses, coupling and reflection will limit the operation frequency.

In the first embodiment of the invention, shown in FIG. 1, connectors 14 are provided to use external test equipment. This is more suited for frequency domain type of measurements with a vector network analyzer (VNA), for example.

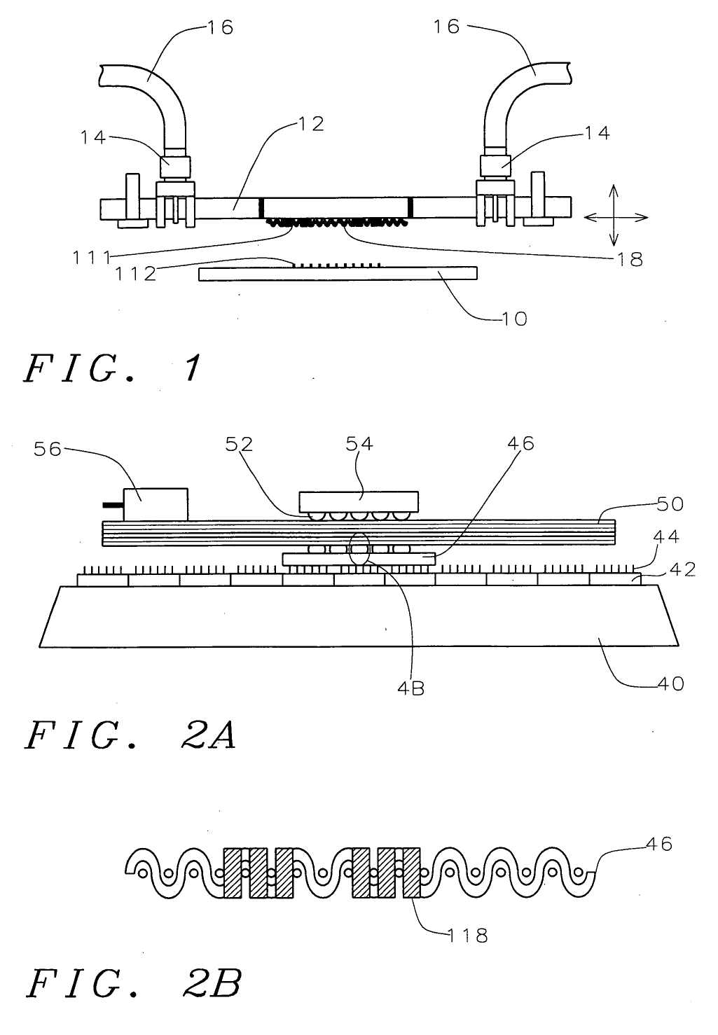

In a second embodiment of the present invention, shown in FIGS. 2A and 2B, a test support processor (TSP) is used to force and detect test signals. This is meant for time domain measurements such as is done in the case of functional testing of wafers and chips. “A MEMS Based Interposer for Nano-Wafer Level Packaging Test” by Deng Chun et al, IEEE 2003 Electronics Packaging Technology Conference, pp. 405-409 describes a TSP where the interposer 46 is a MEMS (micro electro mechanical system) interposer for connection between the WLP and the test circuit. The test methodology of the present invention can be used with a TSP using a compliant sheet mesh in place of the MEMS interposer. The schematic of the system is given in FIG. 2A.

Wafer 42 to be tested is shown on wafer chuck 40. TSP 54 is a test support processor. It consists of electronic circuits to launch and detect high frequency signals on the order of multi Giga Hertz. TSP 54 is connected by solder ball connection 52 to printed circuit board (PCB) 50 which is in turn connected to interposer 46. Pins 44 on the wafer 42 are connected to the interposer 46 for testing the wafer or WLP.

FIG. 2B shows an expanded view of the compliant sheet interposer 46 of the present invention. The mesh sheet formation 46 is shown as a woven fabric in the wave-like form in one direction and dot-like form in the cross direction. The metallization 118 oozes through the gaps of the mesh to facilitate connections on either side of the mesh. The top side of the metallization 118 connects to the multi-layer substrate 50 either through a soldering contact or a pressure contact. The bottom side connection to the WLP 42 is purely a pressure contact. Though the mesh is shown in the figure to be a fabric, it is also possible to form the mesh in other forms such as a grid.

The test method of the invention is devised for use with the compliant interposer sheet and multi-layer substrate combination in either the first or the second embodiment. To implement the test method of the invention, the inventors have developed a test vehicle with two components. The first component is a wafer level device under test (DUT), illustrated in FIG. 3. In FIG. 3 is shown the design of a 50 ohm transmission line 110 with coplanar arrangement on high resistivity silicon 100 (2 k Ohm-cm). A silicon dioxide layer 106 lies between the silicon substrate 100 and the transmission line 110. It has been verified that the DUT works to the specification by conventional probing (using an Air Coplanar probe by Cascade Microtech, Beaverton, Oreg., USA).

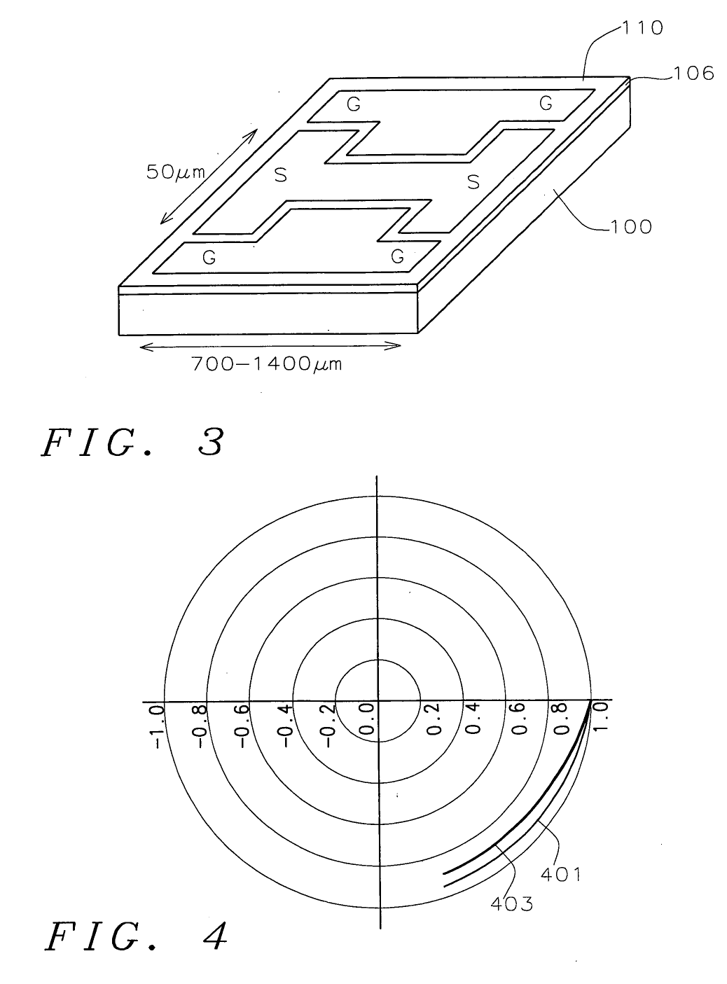

FIG. 4 shows the results of the corresponding simulation on a full wave solver and the measurement. FIG. 4 is a polar plot where the radius gives the strength of the signal. Insertion loss refers to how much of the transmitted signal is lost. Ideally zero loss is the most preferred situation, but due to practical limitations, a certain minimum loss is acceptable. The figure shows the merit of the tested structure. The closeness of the measured (401) and simulated (403) results indicates that we are able to model the structure fairly well.

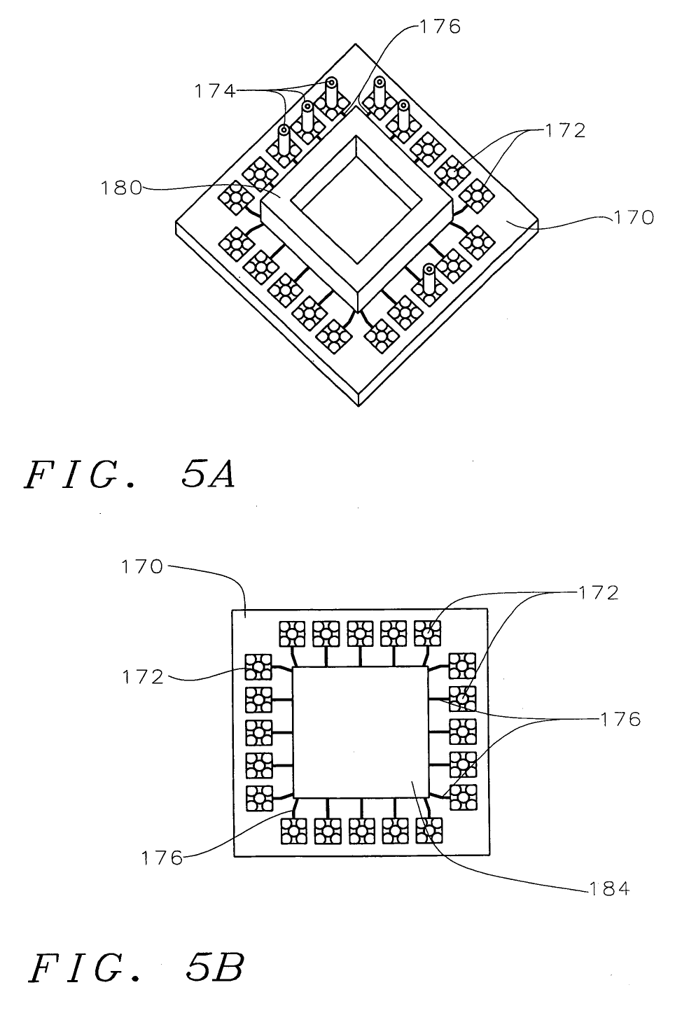

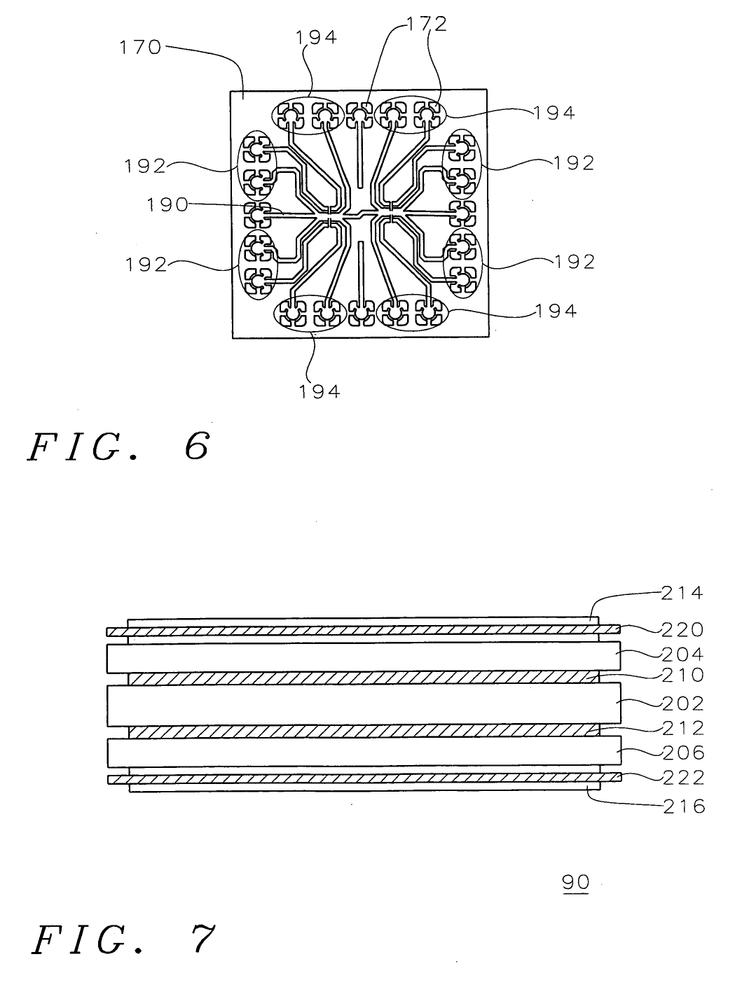

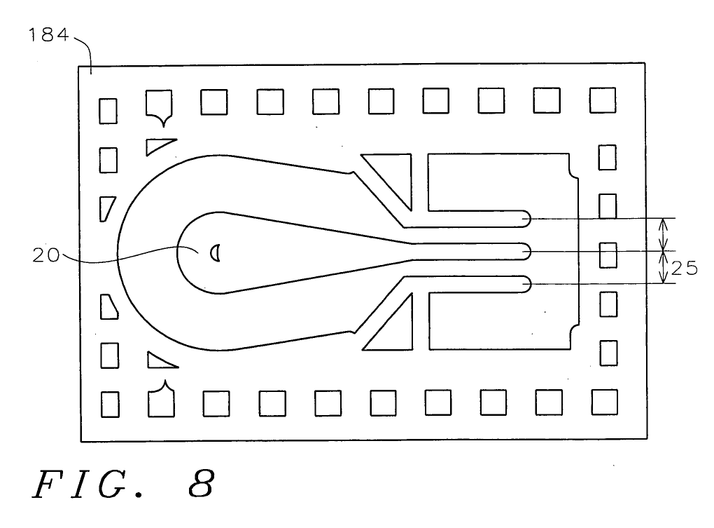

The second component is a prototype hardware that will accommodate the DUT into it for making test measurements. FIGS. 5 and 6 show the prototype. The transmission lines are all designed for 50 ohm impedance match. Calibration is built into the test probe so that the unwanted transmission line characteristics can be de-embedded and the necessary features extracted. There are three sets of calibration lines (open, short, and through). The open and short calibration lines (172) are so-named because at the end of these lines, the DUT poses an open or a short metallization. Lines 190 (FIG. 6) is a through calibration line.

When using the test hardware to analyze an interconnect, the hardware itself consumes some of the test signal energy. So we have to take into account the hardware losses before calculating the losses due to the interconnects. Here we have a calibration line which is simply a matched transmission line with connectors. This line is first measured with the test equipment to see the losses inherent in the test hardware. This measurement data is used to factor into the measurement of the transmission line with WLP interconnect. For example, if 3 dB is the insertion loss due to the hardware, and if 3.6 dB is the insertion loss due to the whole hardware and WLP interconnect, then we can approximately say that 0.6 dB is the insertion loss due to the WLP interconnect alone.

FIG. 5A shows an illustration of the prototype test hardware. FIG. 5B shows a top view of the prototype test hardware 170. Elastic polymer, conductive rubber, trampoline or the like 184 provides a compliant interface between the chip (or wafer or WLP) and the multi-layer substrate. This material is available from vendors of organic/plastic polymer materials.

A semiconductor chip (DUT), such as 100 in FIG. 3, is placed in the socket 180 on the test hardware 170. Connectors 172 surrounding the DUT are to be connected to measurement instruments, such as 174. For example, 172 is a SMA connector. This connector has a good electrical performance up to 18 Gigahertz. 176 refers to the coplanar transmission line on the substrate printed circuit board. Basically it is a ground-signal-ground configuration where the signal line is surrounded by ground lines on both sides in the same plane. This structure offers efficient high frequency transmission.

For example, the 3.5 mm connector 172 can be connected to an instrument 174 such as a vector network analyzer (VNA) terminal. The chip is placed inside the socket 180. The socket guides the chip to sit in line with the compliant sheet probe beneath. The test signal is launched from VNA 174 and passes through the connector 172, through the printed circuit board transmission lines 176, then through the compliant sheet 184 to the chip 180 and back from the chip 180 to the compliant sheet 184, to the probe on the compliant sheet, to the printed circuit board transmission lines 176, to the connector 172 and to the test equipment 174.

To save the cost of building the prototype but at the same time as a proof of concept, we devised this novel chip-based test prototype to mechanically guide the chip to the compliant probe for test. We can build the compliant sheet for the whole wafer, but in that case, the probe card will be mounted on a wafer prober or a flip chip bonder and the alignment will be guided by stepper motors driven by a pattern recognition unit. Then the test equipment could be used for a large scale manufacture of WLP devices.

FIG. 6 is another top view of the prototype test hardware 170. Calibration lines 190 are shown connected to the connectors 172. The calibration line is a reference line that shows the signal losses inherent to the test hardware. Signal in 192 and signal out 194 areas are shown.

FIGS. 7 through 9 show the implementation details of the invention. The invention incorporates a novel concept where a combination of a multi-layer (Pin Electronics) substrate and compliant interposer sheet are used in designing a coplanar wave-guide transmission structure. Pin Electronics is a term used in the ATE (automatic test equipment) industry. The testers use what is called per-pin architecture. That is, for every pin on a chip, there will be a corresponding per-pin resource on the tester. The tester can be programmed so that the per-pin resource could be used as an input or output or both at different times depending on the design of the IC chip. So pin electronics refers to the heavily populated PCB with electronics circuits for forcing and measuring test signals.

As a result of the combination multi-layer substrate and compliant interposer sheet of the invention, we have the fine pitch, high density I/O test methodology that can test future high pin count, fine pitch wafer dies and VLSI chip scale packages at microwave and RF frequencies with less reflection, less coupling, and less insertion loss. The built-in compliance of the interposer provides for the thickness variation of the DUT thereby maintaining reliable electrical contacts over a wide area of square centimeters.

The main idea behind the present invention is that a two dimensional array of probes is provided for mechanical stability while also making good electrical contact without breaking the device under test or the probe. The probe card 170 consists of a compliant interposer sheet 184 and a multi-layer substrate 90, illustrated in FIG. 7. The sheet 184 is formed of elastic polymer, conductive rubber, or the like. Contact electrodes on the sheet 184 (not shown in FIG. 5B) are made by selectively depositing copper metal on the sheet. Precious metal plating (Au or the like) on copper is done to improve the contact. The provision of mesh or pores in the sheet allows the metal to diffuse out on either side of the sheet. On one side of the sheet, a contact probe (electrode) is connected to the wafer level device under test such as 100, shown in FIG. 3. The other side of the sheet is connected to the multi-layered substrate, shown in FIG. 7, which is a low loss epoxy resin or microwave laminate material.

For example, as shown in FIG. 7, the multi-layer substrate 90 may comprise layers of glass bismaleimide-triazine (BT) resin 202, 204, and 206. The central resin layer 202 may have a thickness of between about 200 and 2000 microns. Resin layers 204 and 206 over and under the central layer 202 may have a thickness of between about 100 and 1000 microns. Copper plating 210 and 212 separates the resin layers. For example, the copper plating layers 210 and 212 may have a thickness of between about 35 and 140 microns. Resist layers 214 and 216 are formed on the top side of resin layer 204 and the bottom side of resin layer 206 to enclose the structure. Copper platings 220 and 222 are formed within the resist layers 214 and 216, respectively. For example, the copper platings are formed by squeezing the copper paste with a binder through a screen and emulsion or by electro-deposition. Precious metal plating such as gold may be formed on the copper platings 220 and 222. The total thickness of the multi-layer substrate is between about 600 and 2400 microns. This multi-layer stack is the PCB 170 in FIG. 5A, 12 in FIG. 1, and 50 in FIG. 2A.

The connectors 172 are mounted on a top side layer of the multi-layer stack 90 and the connector pins are soldered on the bottom side layer. For example, the connector 14 is shown in FIG. I mounted on a top side of the probe card or PCB 12, though holes in the PCB and soldered on the bottom side of the PCB 12, as shown.

There are two embodiments on the substrate to support high-speed test. The first embodiment (FIG. 1) is the installation of SMA connectors 172 (14 in FIG. 1) to propagate high-speed signals through the transmission line on the substrate to the interposer electrodes and then to the device and back, as shown in FIG. 5A. The second embodiment (FIG. 2) involves installing high speed signaling electronics close to the electrodes in the test support processor (TSP) silicon chip (or may be SiGe or GaAs chip) with electrical circuits. The electronic circuit in the form of either a multiplexer or phase locked loop generates high frequency signals.

The invention also provides a method of forming a compliant probe card, including the steps of forming contact probes, as shown in FIG. 8. Metallization 20 on the compliant sheet 184 is deposited by screen printing. Other means of metallization such as sputtering may be applied for this. Magnifying the trampoline 184 of FIG. 5B 1000 times would show the probe structures, such as the one probe structure shown in FIG. 8. For example, the pitch between probe tips may be 50 microns, as shown in FIG. 8.

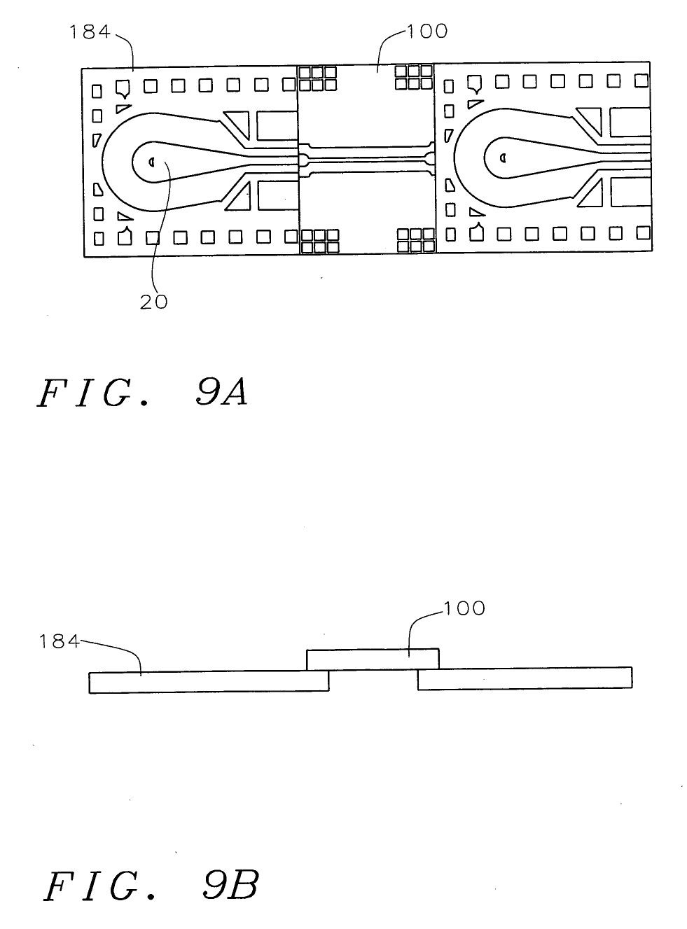

The contact probe pitch 25 is tapered to achieve a smooth transition to minimize signal reflection. As shown in FIG. 9, the narrow end of the contact probe 20 is aligned to the wafer level device under test 100 on one side of the interposer sheet 184 while the broader end of the contact probe is aligned and connected to the multi-layer substrate on the other side of the sheet, not shown. This contact point shall be soldered to fix the sheet to the substrate in position. The coplanar oval/tapered structure provides a space transformer structure.

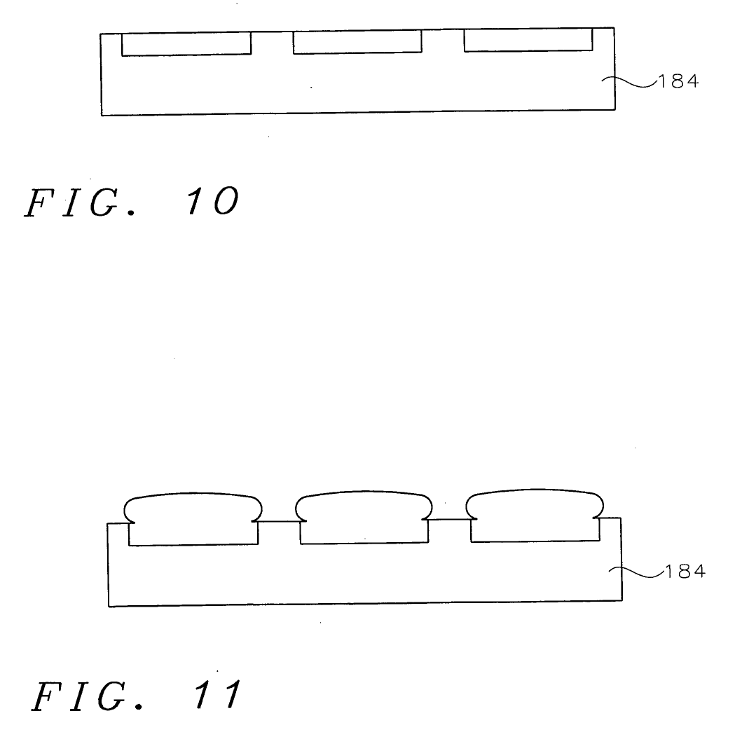

The invention described can be made suitable for probing either plain wafer pads or for wafer level package interconnects by forming the probes in two different ways. The interposer sheet after metallization shall be subject to chemical mechanical polishing (CMP) to smooth the surface for use with wafer level package interconnects, as shown in FIG. 10. For probing of wafers with plain pads, the CMP step may be skipped to keep the protrusions in metallization which naturally act as good contact probes, as shown in FIG. 11. A partial CMP process renders the probes usable for both plain wafers as well as WLP devices (FIGS. 10 and 11). The plain pads are used in wafers for conventional packages. After testing with plain pads, the pads are wire bonded to the lead frames to form packages. But in the case of WLP devices, the pads are populated with interconnects. So the WLP device can be used right away in the application boards.

The invention provides a method for contacting a variety of interconnects such as stretched solder column, bed of nails, and solder balls encountered typically in wafer level packaging. The invention is also usable for a multiplicity of different types of interconnects that can be probed.

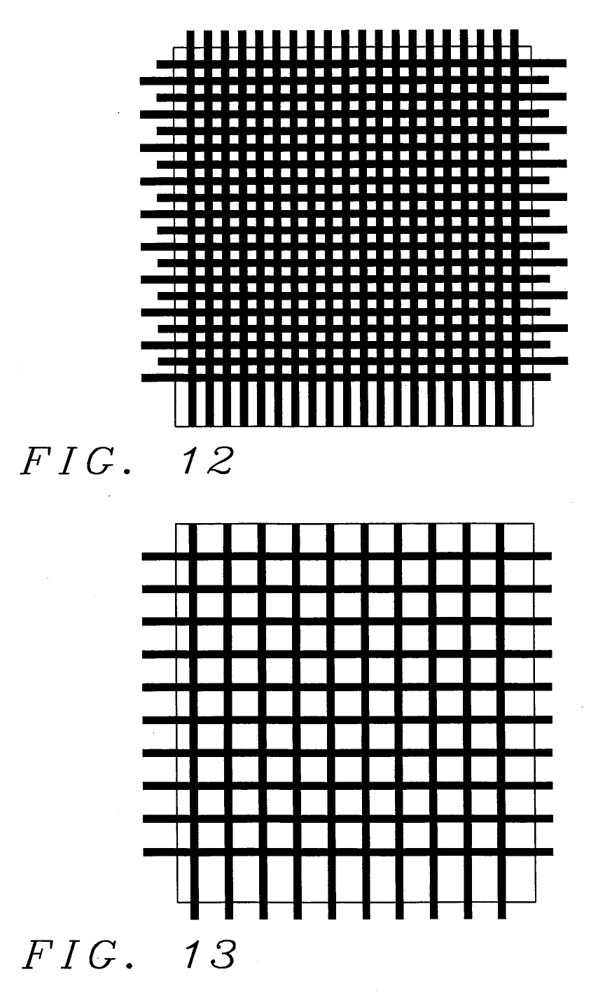

The invention provides a method for designing the interposer sheet mesh for either reducing the coupling noise or reducing insertion loss. Reduced coupling is achieved with sparse mesh, as shown in FIG. 13. Reduced insertion loss is achieved with dense mesh, as shown in FIG. 12. The preferred range of filling fraction of the mesh is 20% to 80%.

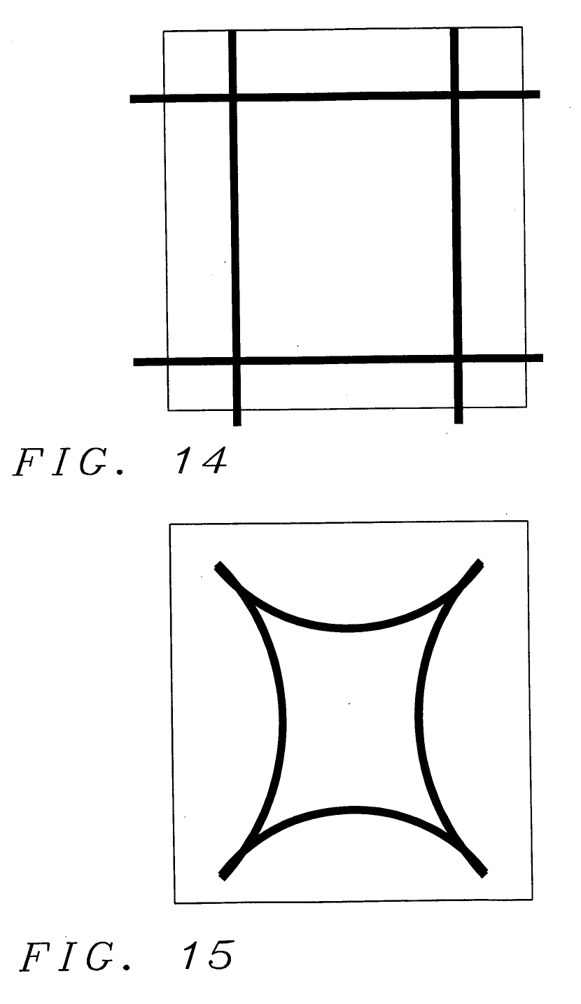

When subjected to higher temperatures such as during hot test, the differences in the thermal coefficients of expansion of the substrate, interposer sheet, and the device substrate cause thermal stresses at the joints of the contacts, but these stresses are accommodated through local relaxation by provision of the mesh formation on the interposer sheet. For example, FIG. 14 illustrates mesh formation at room temperature. FIG. 15 illustrates mesh formation for thermal test at a raised temperature above room temperature. During testing there is no significant change in the mesh configuration. But when the hardware is heated up, the mesh has a slight local deformation to take up a form that conforms to minimum energy, as shown in FIG. 15. The mesh configuration shown is usable for operation in the temperature range of about room temperature of 25° C. to about 125° C.

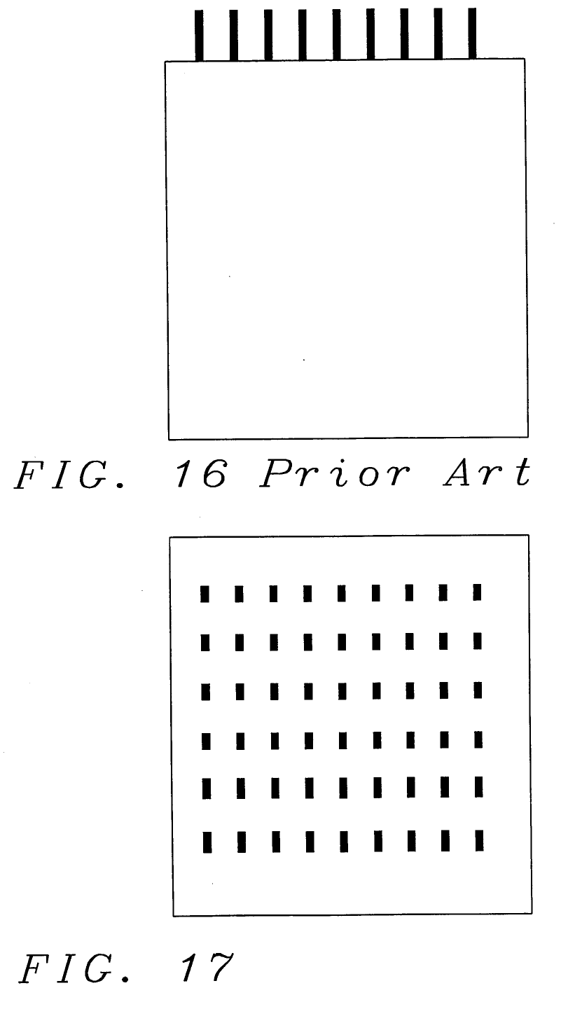

The invention provides a novel application of the interposer probe in automatic test equipment (ATE). Normally the ATE's have vertically placed pin electronic cards with pogo pins for interfacing to the outside world, as shown in FIG. 16. These are very large and they introduce signal degradation while testing at high frequencies. With the interposer probe contacts, it becomes possible to drastically reduce the size of test heads by packing more channels on the pin electronic cards and placing them horizontally and by replacing the pogo pins with interposer contact probes to achieve smaller test heads in ATE, smaller electrical lengths for signals to propagate, and greater signal integrity at multi-gigahertz speeds. The one-dimensional array of pogo pins is replaced by a two-dimensional array of compliant interposer probes, as shown in FIG. 17. The pin count density on the tester increases quadratically by this inventive step.

Model Simulation and Prototype Measurement Results

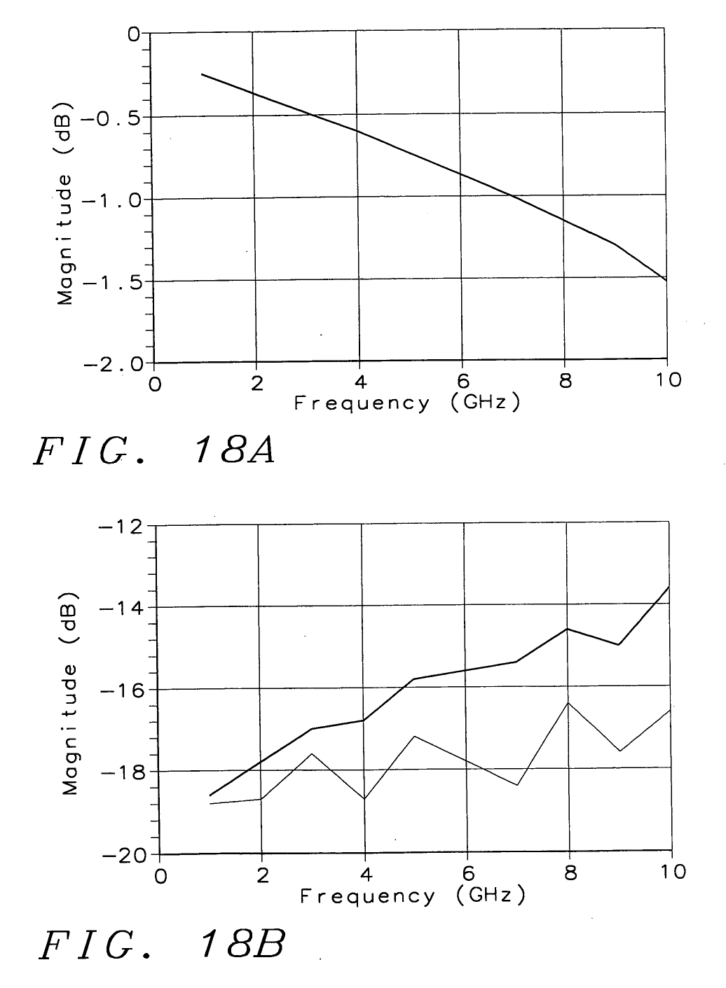

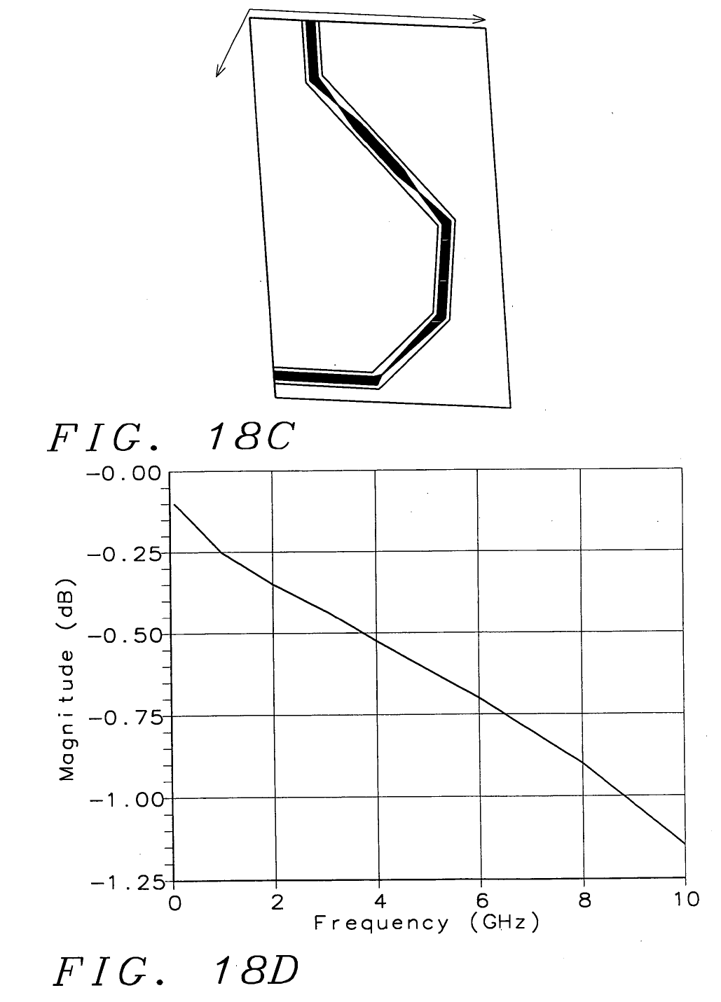

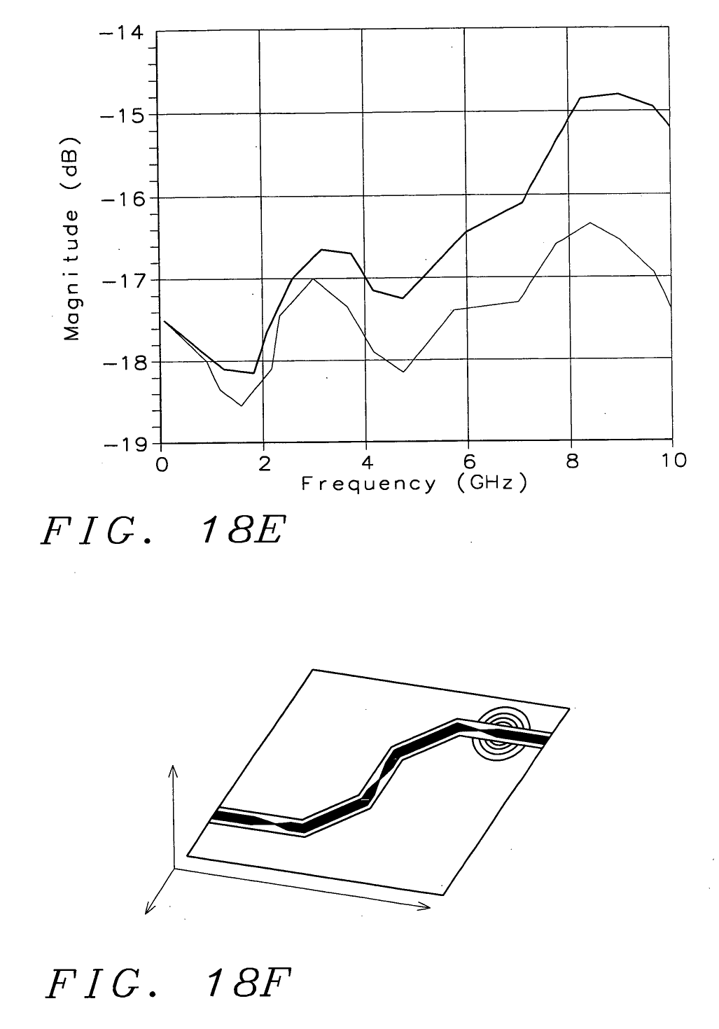

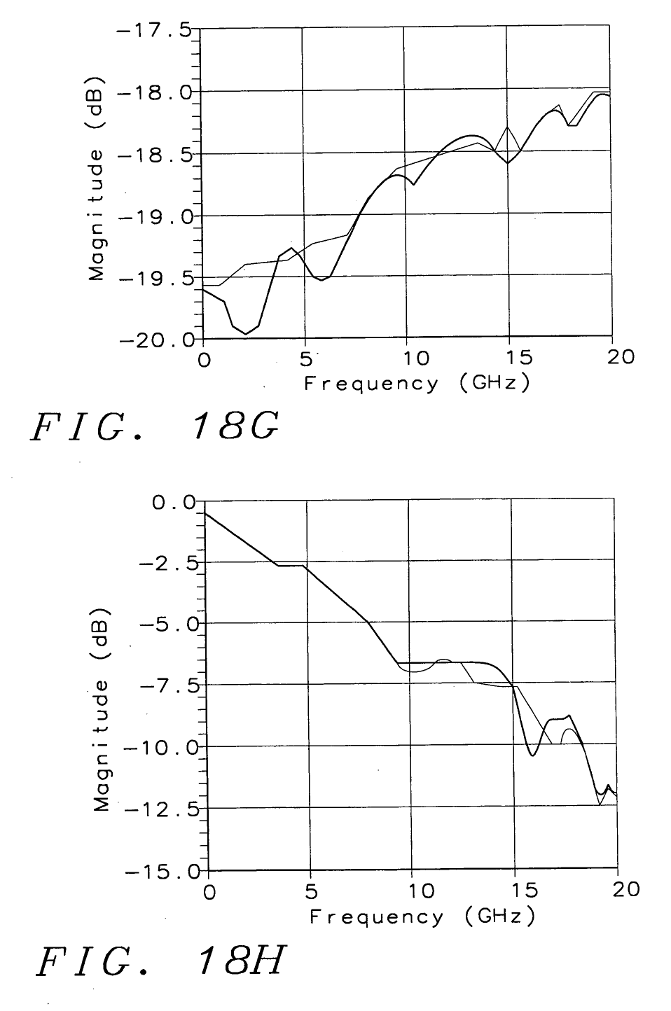

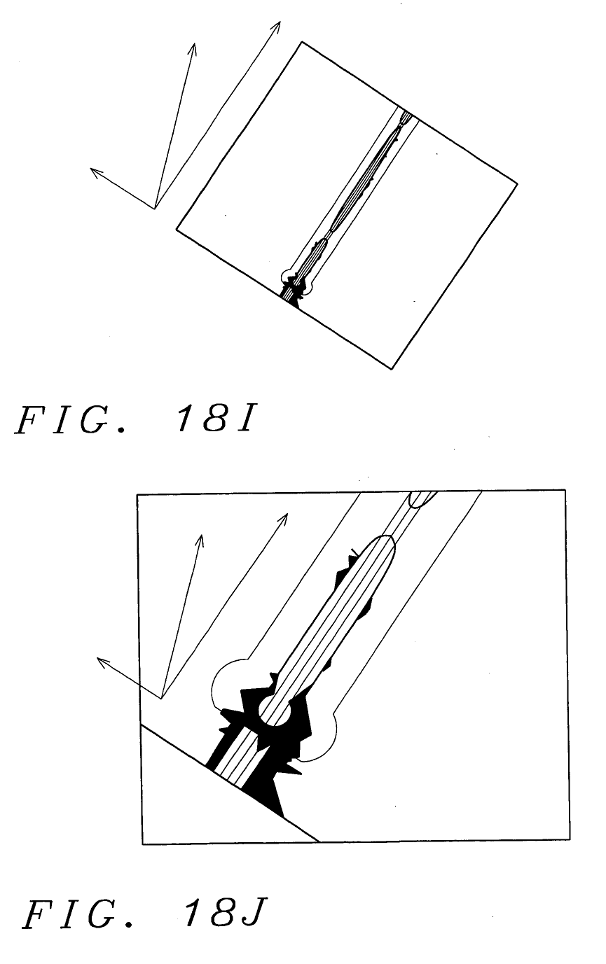

The simulated results (insertion losses) for the PCB-trampoline structure of FIGS. 6 and 7 are presented in FIGS. 18A-18J. The figures refer to transmission line pairing from 192 to 194 as shown in FIG. 6. When the pair is closer to the corner of the PCB, we label it “short” and when the pair is farther from the corner, we label it “long.” It can be seen that the design has insertion loss on the order of 2 dB up to 10 GHz. FIG. 18A shows the insertion loss for the longest transmission line, FIG. 18D shows the insertion loss for the shortest transmission line, and FIG. 18H shows the insertion loss for a straight transmission line. FIGS. 18B (longest transmission line), 18E (shortest transmission line), and 18G (straight transmission line) show that reflections within the traces are on the order of −15 dB throughout the bandwidth of interest. (DC through 10 GHz).

FIG. 18C shows how the electric field is distributed in the longest transmission line in the test hardware. It gives us a certain degree of confidence that the signal could propagate without getting stuck at any particular spot. FIG. 18F shows how the electric field is distributed in the shortest transmission line and FIG. 18I shows how the electric field is distributed in the interposer through a straight transmission line. FIG. 18J is a close-up view of the electric field distribution of FIG. 18I.

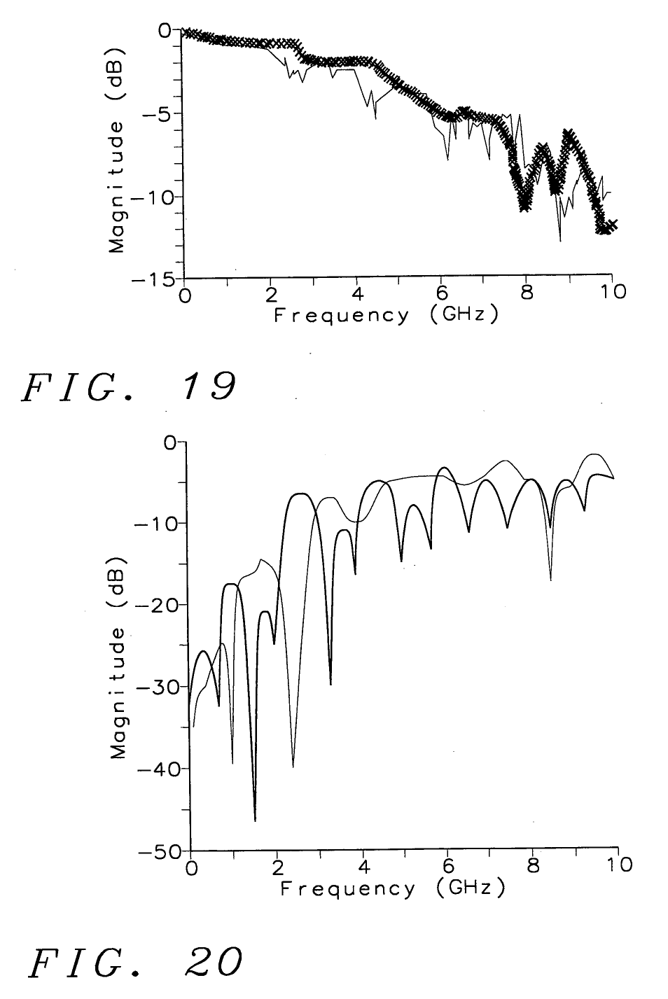

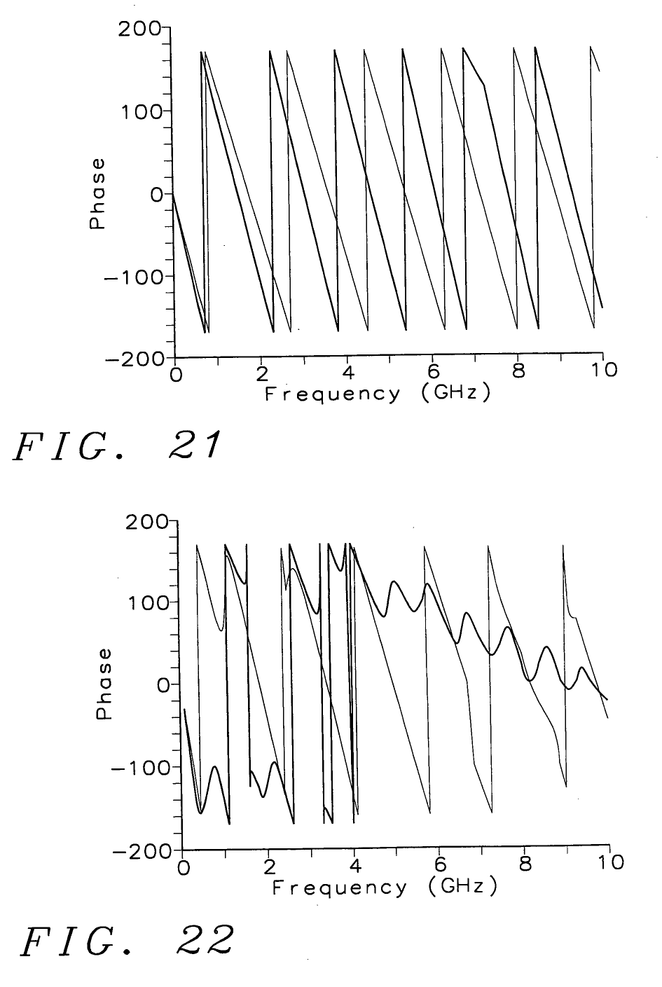

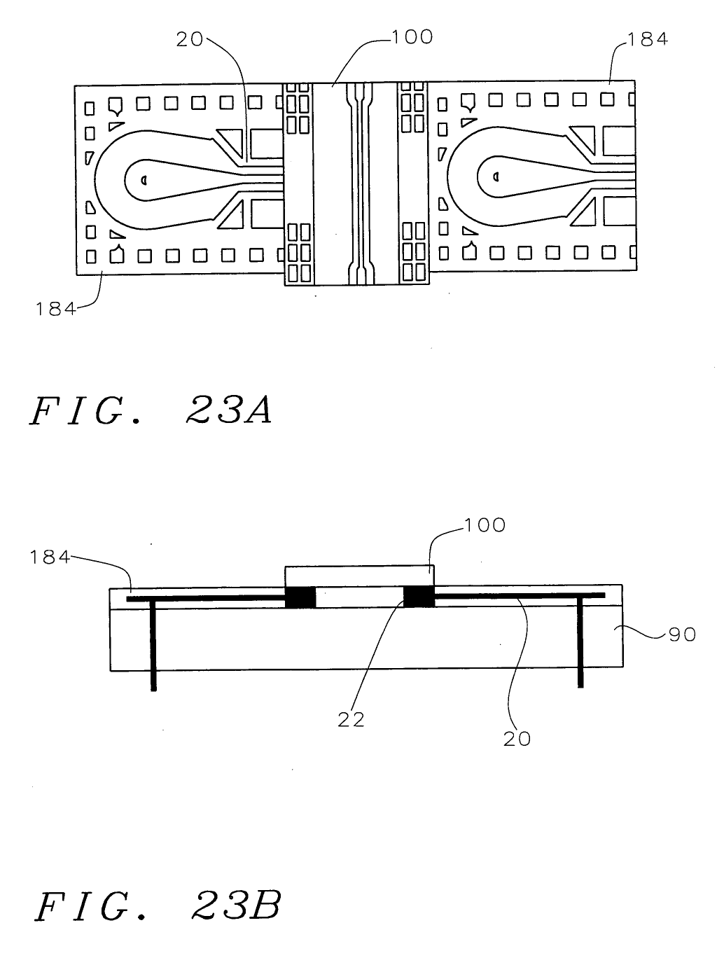

Measurements in FIGS. 19 through 22 show that the prototype performs at 5 GHz with an insertion loss in the range of 3 dB. Since most of the losses are coming from SMA connectors and the PCB substrate, the interposer probe itself is usable to applications at frequencies beyond 10 GHz by using end launch connects and better PCB materials for the multi-layer substrate. For example, Roger 4000 series material (available from Delta Precision Circuits Inc., Elk Grove Village, Ill., USA) and LCP (liquid crystal polymer) are some of the better substrate materials.

Advantages over the Prior Art

The new compliant probe and test methodology of the present invention has at least the following advantages over the related art:

1. The new designs can be used for test applications of both the fine pitch, high pin count flip chip type of packages and for complete wafer testing, up to 10 GHz range. The insertion loss of the probe is on the order of 2 dB.

2. There are no level transitions in the interposer sheet structure. This reduces high frequency signal reflections significantly.

3. The stress due to CTE of the PCB and the wafer is absorbed by the elasticity of the interposer sheet. Unlike the spring contacts for compliance, the sheet itself provides the required compliance. Since the interposer sheet is so thin (between about 30 and 300 microns), it has a near 2D structure, thus providing much better contact stability.

4. By provision of mesh formation in the interposer sheet, the local relaxation during heating releases the thermal stresses and thereby helps to achieve wafer level test and bum-in together.

Testing Methodology

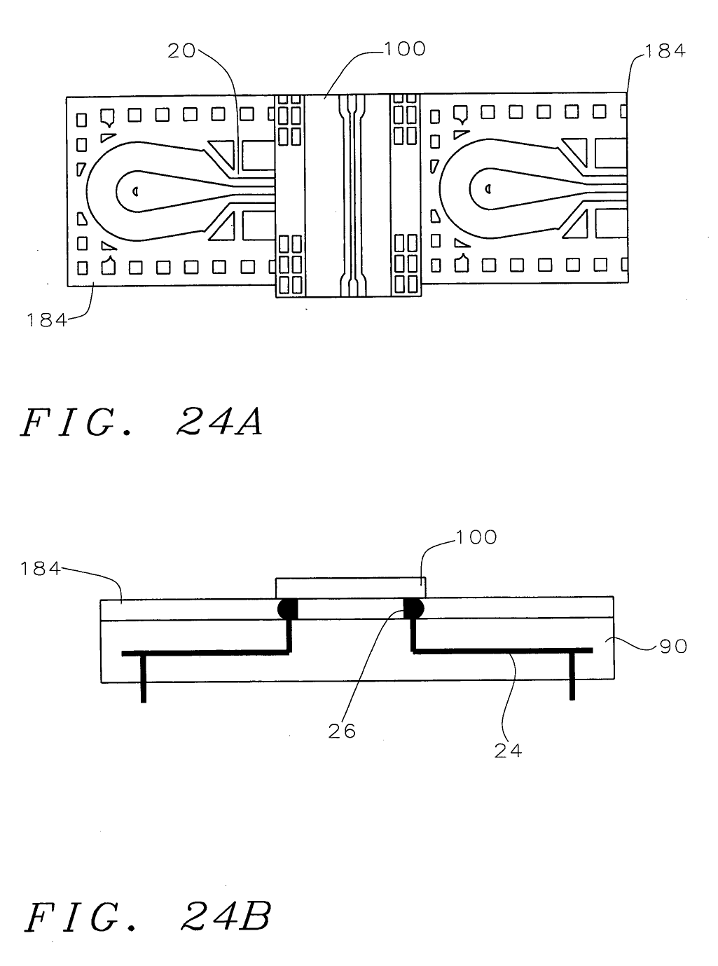

Flip chip test electronics circuits could be packed on one side of the multi-layer substrate while on the other side could be connected the compliant interposer sheet comprising gold-plated copper metallization having coplanar-oval tapered structure to do space transformation between low pitch wafer dies and high pitch PCB circuits that have pin electronics. This arrangement helps to pack about 1000's of test probes per square centimeter. The method is applicable to wafer test and wafer level package test. The test probe density could be increased to 10,000 per square centimeter by forming metal dots on the interposer sheet and implementing the space transformation taper structure in the multi-layer substrate. When the number of signal points in the WLP device grows very huge, that is, of the order of 10,000 pins per square centimeter, there is no room on the compliant sheet itself to do space transformation as in FIG. 8. So this has to be done in the multi-layer substrate. FIG. 23A shows a top view of the probe 20 in the compliant sheet 184. FIG. 23B shows a side view of the same compliant sheet 184, the DUT 100, and the multi-layer substrate 90. The probe space transformer 20 and the probe tip 22 are within the compliant sheet 184 for low pin count applications. For high pin count applications, the probe space transformer 24 is within the multi-layer substrate 90 while the probe tip 26 in dotted form is within the compliant sheet 184 as shown in top view in FIG. 24A and in side view in FIG. 24B.

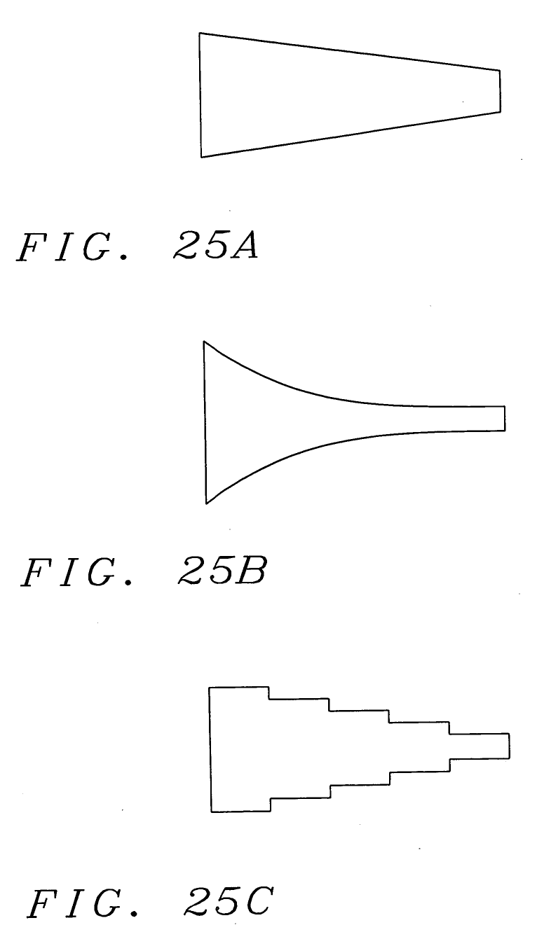

Some possible space transformer structures are shown in FIG. 25. FIG. 25A shows a linear taper, such as used in the prototype probe shown in FIG. 8. FIG. 25B shows a non-linear or “horn-shaped” taper. FIG. 25C shows a stepped taper. These different probe shapes all give good bandwidth for high frequency test applications. These space transforming structures can be implemented either on the compliant interposer sheet as probes or as metallization in the interior layers of the multi-layer substrate.

The discrete meshing concept of the interposer sheet accommodates lateral compliance needs for thermal test. When the device is subject to thermal test, there is an expansion or contraction of the device sideways. So there is a need for flexibility to accommodate this sideways expansion/contraction. The mesh type of structure is discrete as against a continuum structure and is much better suited to accommodate the thermal stresses by local relaxation.

For efficiently testing the wafers, the electrical contact is very crucial. If the device to be tested is a WLP, the interconnect itself presents a sharp pin so the probe needs to be a simple 2D surface to make good contact. The interposer sheet without metallic protrusions (flat metal surface) is used for testing wafer level packages. But, if the device to be tested is a plain wafer with pads, the pad is a 2D and if the probe also is a 2D surface, they may not form a good contact. So a slight amount of projection or protrusion of the probe metallization will enhance the contact in case of plain wafers. The interposer sheet with metallic protrusions is used for testing conventional wafers.

The method and device of the invention can also be used for die socket testing of fine pitch wafer level devices at multi-Gigahertz frequencies. That is, individual dies of the wafer may be tested in this way. The prototype test hardware shown in FIG. 5A is a die socket tester.

The multi-layer substrate—compliant interposer sheet combination of the invention can be used for probing fine pitch wafer level devices at multi-GHz frequencies by fixing the combination directly on the wafer probers or flip-chip bonders. ATE pin electronics—interposer sheet system can be used for directly testing devices without the intermediate DUT boards. In this method, Pogo pins are replaced by interposer sheet probes.

The specifications met by the test methodology of the present invention include:
1. high frequency operation of up to 20 GHz,
2. high temperature operation of up to 125° C. for continuous operation for an extended duration,
3. high pin count density of more than 1000-10,000 per square centimeter, and
4. low contact resistance of less than 0.5 ohm.

While the invention has been particularly shown and described with reference to the preferred embodiments thereof, it will be understood by those skilled in the art that various changes in form and details may be made without departing from the spirit and scope of the invention.

What is claimed is:

1. A method for testing a wafer or a wafer level package comprising:
connecting test electronic circuits on one side of a multi-layer substrate;
connecting a top side of a compliant interposer sheet to an opposite side of said multi-layer substrate; and
contacting a wafer or a wafer level package to be tested on a bottom side of said compliant interposer sheet whereby said wafer or wafer level package can be tested.

2. The method of claim 1 wherein said compliant interposer sheet comprises copper metallization having a space transformer structure.

3. The method of claim 1 wherein said space transformer structure has a linear taper, a non-linear taper, or a stepped taper.

4. The method of claim 1 wherein said compliant interposer sheet performs space transformation between different heights of interconnects on said wafer or wafer level package to be tested.

5. The method of claim 1 wherein thousands of test probes per square centimeter are contained in said compliant interposer sheet

6. The method of claim 1 wherein said compliant interposer sheet has metallic protrusions for testing said wafer.

7. The method of claim 1 wherein said compliant interposer sheet has a flat metal surface for testing said wafer level package.

8. The method of claim 1 further comprising heating said wafer or wafer level package being tested wherein said compliant interposer sheet accommodates thermal stresses through local relaxation.

9. The method of claim 1 wherein said method can be used in high frequency operation of up to 20 gigahertz.

10. The method of claim 1 wherein said method can be used in high temperature operation of up to 125° C.

11. The method of claim 1 wherein said test electronic circuits comprise automatic test equipment wherein pin electronic cards interface with a two-dimensional array of contact probes on said compliant interposer sheet.

12. The method of claim 1 wherein said test electronic circuits comprise a test support processor.

13. A method for fabricating a compliant interposer sheet probe card for wafer level testing or wafer level package testing comprising:
forming a multi-layer substrate;
forming a compliant interposer sheet;
depositing metallization on said compliant interposer sheet to form contact probes;
connecting said contact probes at one end to said multi-layer substrate; and
aligning an opposite end of said contact probes to a wafer or to a wafer level package to be tested.

14. The method of claim 13 wherein said multi-layer substrate is formed of low loss resin or microwave laminate material.

15. The method of claim 13 wherein said compliant interposer sheet comprises elastic polymer, conductive rubber, or other compliant material.

16. The method of claim 13 wherein said compliant interposer sheet has a thickness of 30 to 300 microns.

17. The method of claim 13 wherein said depositing metallization comprises screen printing, sputtering, or selectively depositing copper on said compliant interposer sheet.

18. The method of claim 17 further comprising precious metal plating on said copper.

19. The method of claim 13 wherein said compliant interposer sheet comprises mesh or pores so that said metallization diffuses out on either side of said compliant interposer sheet.

20. The method of claim 19 wherein said mesh has a filling fraction of between 20% and 80%.

21. The method of claim 13 further comprising connecting a measurement instrument to a connector on said multi-layer substrate to propagate high speed signals through a transmission line on said multi-layer substrate to said contact probes to a device on said wafer or said wafer level package and back to said contact probes, through said transmission line, and to said measurement instrument.

22. The method of claim 13 further comprising installing an electronic circuit on a test support processor close to said contact probes to generate high frequency signals.

23. The method of claim 22 wherein said electronic circuit comprises a multiplexer or a phase locked loop.

24. The method of claim 13 wherein said contact probes are tapered such that a narrow end of said contact probe is aligned to said wafer or wafer level package to be tested and wherein a broader end of said contact probe is aligned and connected to said multi-layer substrate.

25. The method of claim 13 further comprising planarizing said compliant interposer sheet after said step of depositing metallization wherein said compliant interposer sheet has a smooth surface for testing a wafer level package.

26. The method of claim 13 further comprising partially planarizing said compliant interposer sheet after said step of depositing metallization wherein said compliant interposer sheet has protrusions that can act as contact probes for testing a wafer and wherein said planarized surface is smooth enough for testing a wafer level package.

27. The method of claim 13 wherein said probe card comprises a coplanar wave-guide transmission structure.

28. A compliant interposer sheet probe card for wafer level testing or wafer level package testing comprising:
a multi-layer substrate;
a compliant interposer sheet; and
contact probes on said compliant interposer sheet wherein one end of said contact probes is connected to said multi-layer substrate and an opposite end of said contact probes is aligned to a wafer or to a wafer level package to be tested.

29. The probe card of claim 28 wherein said multi-layer substrate comprises low loss resin or microwave laminate material.

30. The probe card of claim 28 wherein said compliant interposer sheet comprises elastic polymer, conductive rubber, or other compliant material.

31. The probe card of claim 28 wherein said compliant interposer sheet has a thickness of between about 30 and 300 microns.

32. The probe card of claim 28 wherein said contact probes comprise copper.

33. The probe card of claim 32 further comprising precious metal plating on said copper.

34. The probe card of claim 28 wherein said compliant interposer sheet comprises mesh or pores.

35. The probe card of claim 34 wherein said mesh has a filling fraction of between about 20% and 80%.

36. The probe card of claim 28 wherein said contact probes are tapered such that a narrow end of said contact probe is aligned to said wafer or wafer level package to be tested and wherein a broader end of said contact probe is aligned and connected to said multi-layer substrate.

37. The probe card of claim 28 wherein said compliant interposer sheet has a smooth surface for testing a wafer level package.

38. The probe card of claim 28 wherein said compliant interposer sheet has protrusions on its surface that act as contact probes for testing a wafer.

39. The method of claim 28 wherein said compliant interposer sheet has protrusions that can act as contact probes for testing a wafer and wherein its surface is also smooth enough for testing a wafer level package.

40. The method of claim 28 wherein said compliant interposer sheet accommodates thermal stresses through local relaxation.
